(19) United States
(12) Patent Application Publication
(10) Pub. No.: US 2011/0120540 A1
(43) Pub. Date: May 26, 2011

(54) QUANTUM DOT DYE-SENSITIZED SOLAR CELL

(75) Inventors: Kun-Ping Huang, Miaoli County (TW); Chih-Yung Huang, Taichung County (TW); Chien-Chih Chen, Taichung County (TW)

(73) Assignee: INDUSTRIAL TECHNOLOGY RESEARCH INSTITUTE, Hsinchu (TW)

(21) Appl. No.: 12/953,464

(22) Filed: Nov. 24, 2010

(30) Foreign Application Priority Data
Nov. 24, 2009 (TW) 98140008
Nov. 23, 2010 (TW) 99140432

(51) Int. Cl. H01L 31/06

(52) U.S. Cl. 136/255

(57) ABSTRACT

A quantum dot dye-sensitized solar cell (QDDSSC) including an anode, a cathode, and an electrolyte between the anode and the cathode is provided. The anode includes a semiconductor electrode layer adsorbed with a dye, a plurality of quantum dots distributed within the semiconductor electrode layer, and a plurality of metal nanoparticles distributed within the semiconductor electrode layer. Because the absorption spectra of the quantum dots, the dye, and the semiconductor electrode layer cover the infrared (IR), visible, and ultraviolet (UV) regions of the solar spectrum, IR to UV light in the solar spectrum can be effectively absorbed, and accordingly the conversion efficiency of the solar cell can be improved. Moreover, the metal nanoparticles can increase the light utilization efficiency.

### CROSS-REFERENCE TO RELATED APPLICATION

This application claims the priority benefits of Taiwan application serial no. 98140008, filed on Nov. 24, 2009 and Taiwan application serial no. 99140432, filed on Nov. 23, 2010. The entirety of each of the above-mentioned patent applications is hereby incorporated by reference herein and made a part of this specification.

### TECHNICAL FIELD

The disclosure relates to a quantum dot dye-sensitized solar cell (QDDSSC).

### BACKGROUND

Solar cell is a clean energy source that converts the energy of sunlight directly into electricity. In recent years, dye-sensitized solar cell has become one of the most potential solar cells because it offers a much lower cost than other types of solar cells.

The energy of solar radiation is mainly distributed within the visible and infrared (IR) regions of the solar spectrum, wherein the energy distributed within the visible region takes up 50% of the total amount of solar radiation, the energy distributed within the IR region takes up 43% of the total amount of solar radiation, while the energy distributed within the ultraviolet (UV) region takes up only 7% of the total amount of solar radiation. However, the absorption spectrum of a conventional dye-sensitized solar cell only covers the visible and UV regions, while the red and IR regions that take up about 50% of the total amount of solar radiation is not taken in. Thus, the module efficiencies of both conventional dye-sensitized solar cell and conventional quantum dot sensitized solar cell are lower than 10%. Even though the experimental conversion efficiency of dye-sensitized solar cell is up to 12% and the module conversion efficiency thereof may even be over 10%, it is still difficult to popularize dye-sensitized solar cell because the dye used therein is very costly.

A technique of adding colloidal metal nanoparticles into a dye-sensitized solar cell has been provided, wherein the optical absorption ability of the dye is enhanced through the surface plasmon on the nanosized particles, so that the conversion efficiency of the solar cell is improved (please refer to U.S. Patent No. 2009/0032097 Al).

However, since the absorption spectrum of foregoing dye-sensitized solar cell still only covers the visible and UV regions of the solar spectrum, the conversion efficiency of the solar cell cannot be greatly improved.

### SUMMARY

A quantum dot dye-sensitized solar cell (QDDSSC) is introduced herein to enhance the absorption of IR (infrared) light and the optical absorption ability of the dye.

The disclosure provides a QDDSSC including an anode, a cathode, and electrolyte between the anode and the cathode. The anode including a semiconductor electrode layer absorbed with a dye, quantum dots distributed within the semiconductor electrode layer, and metal nanoparticles distributed within the semiconductor electrode layer.

As described above, in the present disclosure, dye, metal nanoparticles, and quantum dots are added into a semiconductor electrode layer of a QDDSSC. Because the absorption spectra of the quantum dots, the dye, and the semiconductor electrode layer cover the IR, visible, and UV regions in the solar spectrum, IR to UV light in the solar spectrum can be effectively absorbed, and accordingly the conversion efficiency of the solar cell can be improved. Moreover, because the surface plasmon effect on the metal nanoparticles can enhance the optical absorption ability of the dye, the light utilization effeciency can be increased.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a diagram of a quantum dot dye-sensitized solar cell (QDDSSC) according to a first embodiment of the disclosure.

FIG. 2 is a diagram illustrating an absorption spectrum of the QDDSSC in the first embodiment.

FIGS. 3A-3B are diagrams illustrating the fabrication process of an anode of a QDDSSC according to a second embodiment of the disclosure.

FIG. 4 is a flowchart illustrating the fabrication process of a QDDSSC according to a third embodiment of the disclosure.

FIG. 5 illustrates the photocurrent densities and voltages (I-V) of a dye-sensitized solar cell in experiments 1-3 and a comparative experiment.

### DETAILED DESCRIPTION OF DISCLOSED EMBODIMENTS

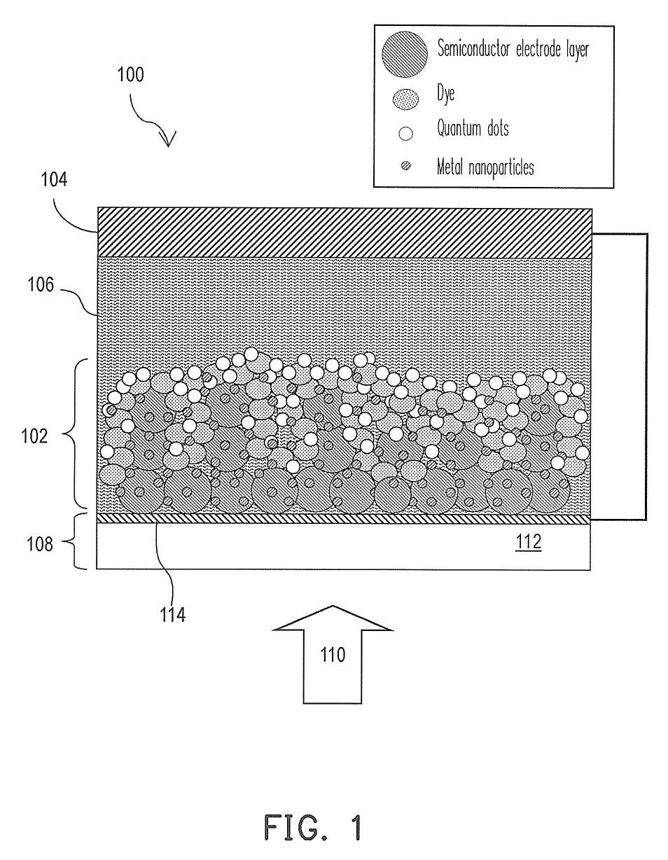

FIG. 1 is a diagram of a quantum dot dye-sensitized solar cell (QDDSSC) according to a first embodiment of the disclosure.

Referring to FIG. 1, in the present embodiment, the QDDSSC 100 includes an anode 102, a cathode 104, and an electrolyte 106 between the anode 102 and the cathode 104. The anode 102 includes a semiconductor electrode layer absorbed with a dye, quantum dots distributed within the semiconductor electrode layer, and metal nanoparticles distributed within the semiconductor electrode layer. The anode 102 of the QDDSSC 100 is usually formed on a transparent conductive substrate 108, and a light beam 110 enters from a transparent substrate 112 at the anode 102. The transparent conductive substrate 108 includes the transparent substrate 112 and a conductive layer 114, wherein the conductive layer 114 may be made of ITO, FTO, AZO or graphene. In the present embodiment, the dye takes up 1 vol. % to 20 vol. % of the semiconductor electrode layer. In the present embodiment, the quantum dots take up 1 vol. % to 20 vol. % of the semiconductor electrode layer, and the semiconductor electrode layer may be formed by a plurality of nanoparticles. In the present embodiment, the metal nanoparticles take up 0 (exclusive) to 10 vol. % of the semiconductor electrode layer. Aforementioned percentages can be changed according to the materials or particle diameters of the dye, the quantum dots, and the metal nanoparticles.

In FIG. 1, the material of the semiconductor electrode layer may be TiO₂, N-doped TiO₂, ZnO, and so on, preferably N-doped TiO₂. N-doped TiO₂ absorbs solar lights having wavelengths below 450 nm, and compared to TiO₂ and ZnO which absorbs solar lights having wavelengths below 380 nm, N-doped TiO₂ absorbs at least 50% more UV light in the solar spectrum. Moreover, the material of the semiconductor electrode layer may be N-doped TiO₂ with metal nanoparticles on a surface thereof.

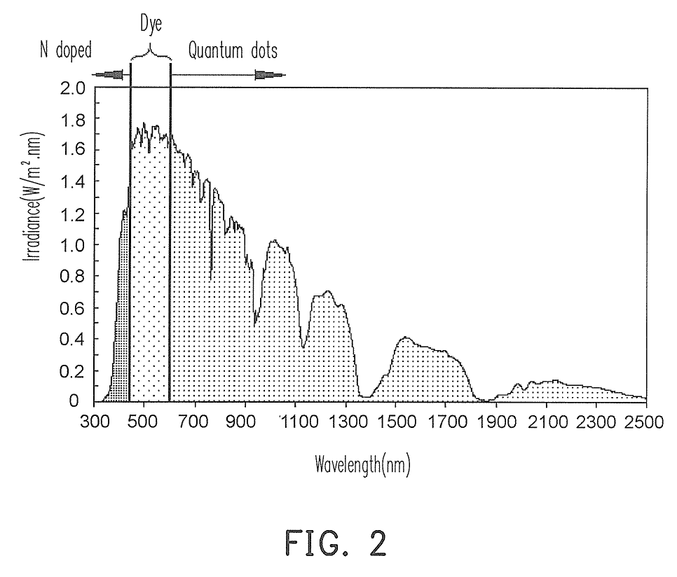

FIG. 2 is a diagram illustrating an absorption spectrum of the QDDSSC in the first embodiment. As shown in FIG. 2, the QDDSSC in the present embodiment covers almost the entire solar spectrum.

Referring to FIG. 1 again, in the present embodiment, the quantum dots offer a quantum confinement effect, an impact ionization effect, and a miniband effect therefore can increase photocurrent, photovoltage, and accordingly the energy conversion efficiency of the QDDSSC. In the present embodiment, the energy gap of the quantum dots is preferably smaller than that of the dye, the material of the quantum dots is GaSb, PbS, InSb, InP, InN, InAs, GaAs, CdS, CdTe, CIS, CGS, or CIGS, and the particle diameter thereof is smaller than 50 nm (for example, between 5 nm and 40 nm). In addition, by adding the quantum dots into the semiconductor electrode layer, not only the absorption ability of IR light increased, but the quantity of dye used is reduced so that the cost of the QDDSSC is also reduced. As to the metal nanoparticles in the semiconductor electrode layer, because they produce a surface plasmons resonance (SPR) effect, an intensive near-field enhancement electromagnetic field is induced close to the surfaces of the metal nanoparticles, which may catalyze light-induced physical and chemical reactions. In the present embodiment, the material of the metal nanoparticles is Ag, Au, or Cu (preferably Ag), and the particle diameter of the metal nanoparticles is smaller than 50 nm. The SPR effect of the metal nanoparticles can increase the absorption coefficient of the dye in the semiconductor electrode layer and accordingly improve the energy conversion efficiency of the QDDSSC. The dye may be a ruthenium compound such as N3 dye, N719 dye (cis-di(thiocyanato)-bis(2,2′-bipyridyl-4-carboxylate-4′-carboxylic acid)-ruthenium(II)), black dye, K77, or K19. Alternatively, the dye may be anthocyanidins or chlorophyll.

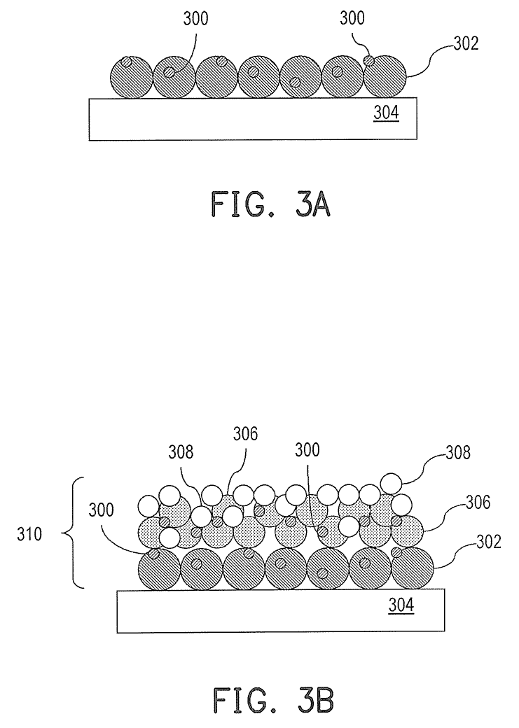

FIGS. 3A-3B are diagrams illustrating the fabrication process of an anode of a QDDSSC according to a second embodiment of the disclosure.

Referring to FIG. 3A, nanoparticles are first prepared in a N-doped TiO₂ 302, wherein there are metal nanoparticles 300 on the surface of the N-doped TiO₂ 302, and the technique for preparing the nanoparticles may be an existing technique, such as that described in “Photocatalytic Synthesis of Silver Nanoparticles Stabilized by TiO₂ Nanorods: A Semiconductor/Metal Nanocomposite in Homogeneous Nonpolar Solution” published by Cozzo in 2004 at pages 3868-3879 of the Journal of American Chemical Society 126 and in “Preparation of N-doped TiO₂ photocatalyst by atmospheric pressure plasma process for VOCs decomposition under UV and visible light sources” published by Chen in 2007 at pages 365-375 of the Journal of Nanoparticle Research 9. Then, the N-doped TiO₂ 302 with the metal nanoparticles 300 is coated on a transparent conductive substrate 304.

Next, referring to FIG. 3B, the metal nanoparticles 300 is mixed with a dye 306 and quantum dots 308, and the mixture is coated on the N-doped TiO₂ 302 with the metal nanoparticles 300 on its surface to form an anode 310 of the QDDSSC.

The second embodiment described above is only an fabrication example of the anode of the QDDSSC in the disclosure but not intended to limit the scope of the disclosure.

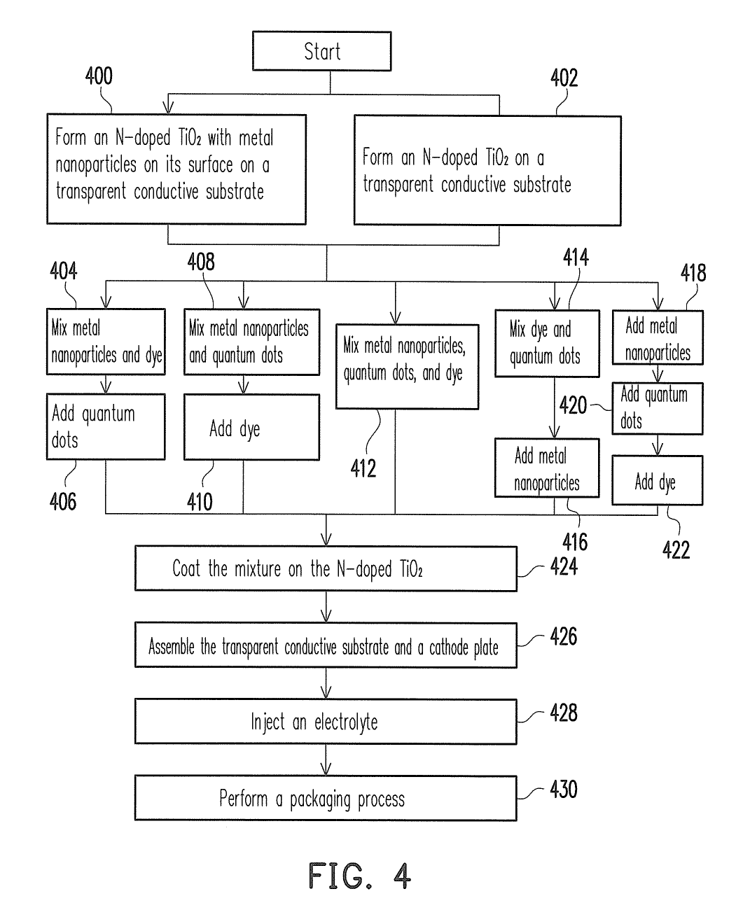

FIG. 4 is a flowchart illustrating the fabrication process of a QDDSSC according to a third embodiment of the disclosure.

Referring to FIG. 4, the present embodiment provides different processes for fabricating the anode of a QDDSSC. First, step 400 or 402 is executed to fabricate a semiconductor electrode layer. In step 400, an N-doped TiO₂ with metal nanoparticles on its surface is formed on a transparent conductive substrate through the fabrication process published by Cozzo in 2004 or the one published by Chen in 2007, as described in the second embodiment. Additionally, in step 402, the N-doped TiO₂ is only formed on the transparent conductive substrate through a plasma-enhanced chemical vapor deposition (PECVD) process, an ion-beam-assisted deposition (IBAD) process, or an atmospheric pressure plasma-enhanced nanoparticles synthesis (APPENS) process. For example, the N-doped TiO₂ is formed through the technique described in “Preparation of N-doped TiO₂ photocatalyst by atmospheric pressure plasma process for VOCs decomposition under UV and visible light sources” published by Chen in 2007 at pages 365-375 of the Journal of Nanoparticle Research 9. Moreover, the N-doped TiO₂ may also be formed on the transparent conductive substrate by using TiO₂ or ZnO.

Thereafter, one of following five processes is selected to prepare a mixture of metal nanoparticles, quantum dots, and dye. First, in steps 404-406, the metal nanoparticles and the dye are mixed, and the quantum dots are then added into the mixture. Moreover, in steps 408-410, the metal nanoparticles and the quantum dots are first mixed, and the dye is then added into the mixture. Step 412 may also be executed to directly mix the metal nanoparticles, the quantum dots, and the dye. In addition, steps 414-416 may be executed, wherein the dye and the quantum dots are first mixed, and the metal nanoparticles are then added into the mixture. The last option is to execute steps 418-422, wherein the metal nanoparticles, the quantum dots and the dye are added in sequence. For example, FIGS. 3A-3B are flowcharts from step 400 to step 412. The materials of the metal nanoparticles, the quantum dots, and the dye can be referred to the first embodiment described above.

Next, in step 424, the mixture containing the metal nanoparticles, the quantum dots, and the dye is coated on the N-doped TiO₂. Thereafter, in step 426, the transparent conductive substrate and a cathode plate are assembled together. In step 428, an electrolyte is injected. Finally, a packaging process is performed in step 430.

The effect of the present disclosure will be verified with following experiments.

### Experiment 1

### Fabrication of a QDDSSC of TiO₂/Quantum Dots/Metal Nanoparticles/N719dye

The steps are as follows.

In step 1, for fabricating a working electrode, a TiO₂ slurry is first prepared, and then a TiO₂ electrode layer with a thickness of 13 μm is formed on a FTO/glass substrate by blade coating. Thereafter, the FTO/glass substrate is put in a high temperature furnace and then sintered for 30 minutes at 450° C.

In step 2, the working electrode of step 1 is dipped into 40 mM TiCl₄ for 30 minutes at 70° C., and then it is put in a high temperature furnace and sintered for 60 minutes at 500° C.

In step 3, a material having metal Au nanoparticles is prepared and then coated on the working electrode of step 2.

In step 4, a material of quantum dots (i.e. CIGS) is prepared, and then the material of quantum dots is formed on the working electrode of step 3 by coating.

In step 5, the resulting working electrode of step 4 is put in the high temperature furnace and then sintered for 10 minutes at 450° C.

In step 6, for fabricating a counter electrode, a Pt electrode layer is formed on a FTO/glass substrate by evaporation.

In step 7, the resulting working electrode in the step 5 is dipped into a N719 dye solution of 3×10⁻⁴ M for 24 hours at room temperature, rinsed by acetone, and then standing dried.

In step 8, the counter electrode in the step 6 and the resulting working electrode in the step 7 are bonded by thermoplastic plastics. Afterward, an acetonitrile-soluble electrolyte incorporating I⁻/I³⁻ as a redox couple is injected into the space between the two electrodes, and then a package process is performed. After that, a testing is done.

### Comparative Experiment

### Fabrication of a Dye-Sensitized Solar Cell of TiO₂/N719dye

The steps in Experiment 1 are repeated except for the steps of adding the quantum dots and the metal nanoparticles.

### Experiment 2

### Fabrication of a QDDSSC of TiO₂/quantum dots/N719dye

The steps in Experiment 1 are repeated except for the step of adding the metal nanoparticles.

### Experiment 3

### Fabrication of a Dye-Sensitized Solar Cell of TiO₂/Metal Nanoparticles/N719dye

The steps in Experiment 1 are repeated except for the step of adding the quantum dots.

### Measurement

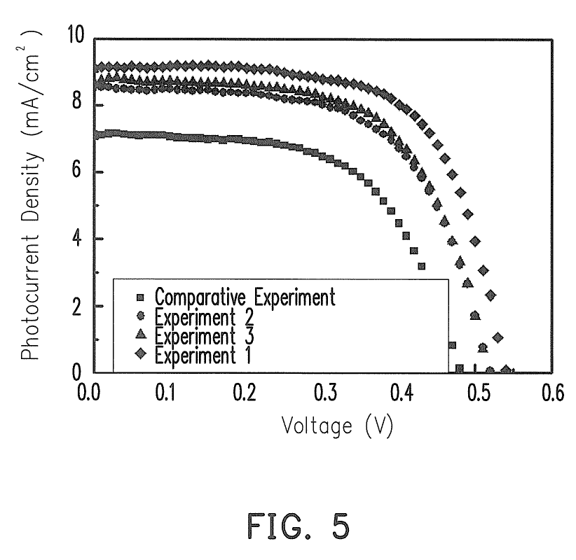

FIG. 5 illustrates the photocurrent densities and voltages (I-V) of a dye-sensitized solar cell in Experiments 1-3 and Comparative experiment. Data measured in foregoing Experiments 1-3 and Comparative experiment are in following table 1, and the efficiencies of the solar cells are calculated.

It can be observed from FIG. 5 and following table 1 that the QDDSSC in experiment 1 offers a much higher efficiency that the solar cells in Experiments 2-3 and Comparative experiment.

TABLE 1

| | Comparative | Experiment | Experiment | Experiment |
|---|---|---|---|---|
| | Experiment | 2 | 3 | 1 |
| Voc (V) | 0.49 | 0.53 | 0.53 | 0.55 |
| Jsc (mA/cm²) | 7.14 | 8.52 | 8.71 | 9.13 |
| FF | 0.59 | 0.60 | 0.61 | 0.64 |
| Efficiency (%) | 2.05 | 2.72 | 2.83 | 3.23 |

In summary, in the present disclosure, because a semiconductor electrode layer, metal nanoparticles, a dye, and quantum dots are all added into a dye-sensitized solar cell, the light absorption of the solar cell is enhanced, and the absorption spectrum thereof covers almost the entire solar spectrum. Thereby, the solar cell in the present disclosure absorbs 50% more lights (i.e. red light and IR light) compared to a conventional dye-sensitized solar cell. Moreover, in the present disclosure, because the quantum dots are mixed into a dye-sensitized solar cell, the quantity of dye used is reduced and accordingly the cost of the solar cell is reduced.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A quantum dot dye-sensitized solar cell (QDDSSC), comprising an anode, a cathode, and an electrolyte between the anode and the cathode, wherein the anode comprises:
a semiconductor electrode layer, absorbed with a dye;
a plurality of quantum dots, distributed within the semiconductor electrode layer; and
a plurality of metal nanoparticles, distributed within the semiconductor electrode layer.

2. The QDDSSC according to claim 1, wherein the dye takes up 1 vol. % to 20 vol. % of the semiconductor electrode layer.

3. The QDDSSC according to claim 1, wherein the quantum dots take up 1 vol. % to 20 vol. % of the semiconductor electrode layer.

4. The QDDSSC according to claim 1, wherein the metal nanoparticles take up 0 (exclusive) to 10 vol. % of the semiconductor electrode layer.

5. The QDDSSC according to claim 1, wherein a material of the semiconductor electrode layer comprises TiO₂, or ZnO.

6. The QDDSSC according to claim 1, wherein a material of the semiconductor electrode layer is N-doped TiO₂.

7. The QDDSSC according to claim 1, wherein a material of the semiconductor electrode layer is N-doped TiO₂ with metal nanoparticles on a surface thereof.

8. The QDDSSC according to claim 1, wherein a material of the metal nanoparticles comprises Ag, Au, or Cu.

9. The QDDSSC according to claim 1, wherein a particle diameter of the metal nanoparticles is smaller than 50 nm.

10. The QDDSSC according to claim 1, wherein the dye comprises a ruthenium compound, anthocyanidins, or chlorophyll.

11. The QDDSSC according to claim 1, wherein an energy gap of the quantum dots is smaller than an energy gap of the dye.

12. The QDDSSC according to claim 1, wherein a material of the quantum dots comprises GaSb, PbS, InSb, InP, InN, InAs, GaAs, CdS, CdTe, CIS, CGS, or CIGS.

13. The QDDSSC according to claim 1, wherein a particle diameter of the quantum dots is smaller than 50 nm.

14. The QDDSSC according to claim 1, wherein the semiconductor electrode layer is formed by a plurality of nanoparticles.

15. The QDDSSC according to claim 14, wherein the metal nanoparticles are formed on surfaces of the nanoparticles.
